(19) United States
(12) Patent Application Publication
(10) Pub. No.: US 2003/0146749 A1
(43) Pub. Date: Aug. 7, 2003

(54) Method for monitoring localized corrosion of a corrodible metal article in a corrosive environment

(76) Inventors: Rengaswamy Srinivasan, Ellicott City, MD (US); Hassan M. Saffarian, Silver Spring, MD (US); Robert Osiander, Ellicott City, MD (US)

Correspondence Address: Francis A. Cooch, THE JOHNS HOPKINS UNIVERSITY, Applied Physics Laboratory, 11100 Johns Hopkins Road, Laurel, MD, 20723-6099, US

(21) Appl. No.: 10/346,001

(22) Filed: Jan. 16, 2003

Related U.S. Application Data
(60) Provisional application No. 60/349,554, filed on Jan. 18, 2002.

(51) Int. Cl. G01N 27/00; G01R 33/00

(52) U.S. Cl. 324/263; 324/71.2

(57) ABSTRACT

A method for detecting the onset of and/or monitoring the progress of localized corrosion of one or more locations on the surface of a corrodible metal article in a corrosive environment is provided which comprises the step of placing one or more magnetic field corrosion sensing devices, e.g., a magnetometer, in juxtaposition with the corrosive metal article, e.g., a steel rebar in concrete, such that the magnetic field corrosion sensing devices can effectively measure the magnetic fields associated with the localized corrosion of the locations on the surface of the corrodible metal article and determine the degree of localized corrosion occurring at the locations on the surface of the corrodible metal article being monitored.

### CROSS-REFERENCE TO RELATED APPLICATION

This application claims priority to U.S. Provisional Application No. 60/349,554, filed Jan. 18, 2002, entitled “Monitoring Pitting and Other Localized Corrosion Activities in Buried and Inaccessible Parts of Structures Using Magnetometers” of Srinivasan et al. The contents of the aforesaid U.S. Provisional Application No. 60/349,554 are incorporated by reference herein.

### BACKGROUND OF THE INVENTION

1. Field of the Invention

The present disclosure relates generally to a method for detecting the onset of and/or monitoring the progress of localized corrosion of a corrodible metal article in a corrosive environment. More particularly, the present disclosure is directed to a method for detecting the onset of and/or monitoring the progress of localized corrosion of a corrodible metal article in a corrosive environment such as, for example, reinforcing steel bars in concrete, by placing a magnetic field corrosion sensing device, e.g., a magnetometer, in juxtaposition with the corrosive metal article such that the magnetic field responsive device can effectively measure the magnetic field associated with the localized corrosion of the corrodible metal article and determine the degree of localized corrosion occurring at the surface of the corrodible metal article.

2. Description of the Relation Art

Corrosion is an electrochemical process involving the flow of electric current across the interface between the surface of a corrodible metal article and its environment. It has long been known that various forms of corrosion exist which result in the destruction of the corrodible metal article such as, for example, rebars such as carbon steel, stainless steel, aluminum and titanium, piping, tanks, chambers and cavities, composite materials and other metal structures. Two major types of corrosion are uniform corrosion and localized corrosion. Uniform corrosion generally includes corrosion of large areas of a corrodible material at a roughly uniform rate. Localized corrosion, e.g., pitting corrosion, is generally smaller scale corrosion which is harder to detect. Localized corrosion occurs initially in a microscopically small area on the surface of the metal article, which eventually becomes larger and deeper, forming pits and eventually cracks in the surface. Localized corrosion, particularly pitting, is hazardous because material is removed in a concentrated area that is not easily recognized. For example, in the United States, billions of dollars have been spent in the construction of highways, freeways and their associated overpasses, bridges and buildings having steel reinforcing rebars located throughout the cement structures. One of the most important problems facing the nation is determining how to maintain the integrity of this system of roads and other structures at an acceptable cost.

Pitting corrosion is the first stage toward more serious forms of localized corrosion of metal articles with a passivation layer, such as, for example, stress corrosion cracking (SCC), hydrogen embrittlement, fatigue and crevice, causing, for example, the roadways and structures formed from the steel reinforced concrete to degrade and ultimately fail. A property that is common to the corrodible metal articles that undergo pitting is that they all have a passivation layer of the metal oxide or other salts on their surface that protects the article from corrosion. In the presence of the passivation layer, the metal article will be less prone to uniform corrosion. However, damaging the passivation layer within a certain location of the article will cause that specific location to corrode. The damage may have been the result of some mechanical, chemical or thermal flow or due to some inherent flaw in the passivation layer. The corrosion process will attempt to “repair” the damage, but the repaired passivation layer may not always be as good as the original layer. If the passivation layer does not repair itself fully and properly, the article will experience further localized corrosion. Most articles that are used as structural materials happen to be alloys of aluminum, titanium and of course carbon steel and stainless steel, and all of them have a passivation layer thus making them all susceptible to all forms of localized corrosion. Thus, it is particularly important to detect the onset of localized corrosion at the earliest stage possible, i.e., the pitting stage.

Damaging the passivation layer will start the corrosion process, and a current will flow through the metal article. When the corrosion product repairs the damage in the passivation layer, the current will diminish or stop entirely. The start/stop process usually occurs in short bursts, giving the current characteristics of current noise. If localized corrosion occurs in several locations in the metal article, then the bursts could occur more frequently. When the localized corrosion spreads from one to several locations on the surface, then at any given time, there could be an ensemble of currents with the characteristic of a “uniform” corrosion activity, and the current may no longer be noisy, but slowly drifting or even stable (constant) which is similar to a direct current. Thus, localized corrosion that has stochastic character initially will generate a current noise. If the corrosion occurs uniformly throughout the surface, it will become much more deterministic, and the associated current will be much less noisy. Generally, localized corrosion is detrimental to structures, while uniform corrosion is not. As a result, it is more important to detect and monitor localized corrosion at an early stage which would result in cost savings because the metal articles could be treated, repaired or replaced only when necessary thus avoiding failures at impromptu moments.

The corrosion process of pitting in most metals and in most mediums is typically accompanied by the generation of a low-amplitude (e.g., less than about 1 mA/cm²), low frequency (e.g., less than about 1 Hz) current noise, (with typical characteristics of what is known as 1/f noise). Even those metal articles that may be undergoing uniform corrosion (as opposed to pitting, which is localized corrosion), generate an equivalent of dc current, and not currents with 1/f characteristic. Moreover, pitting is a random event, occurring aperiodically, and may appear to start and stop randomly over an extended time. Thus, by monitoring the magnetic field, i.e., current noise, associated with the corrodible metal article, it is possible to identify if the article is undergoing pitting corrosion. Monitoring of current noise over an extended period of time provides the number of occurrences of the corrosion event, and an estimate of the cumulative damage to the article caused by pitting.

There is, however, a problem associated with existing techniques for monitoring the current noise generated by localized corrosion of a corrodible metal article, that is there needs to be a direct electrical contact between the corrodible metal article to be monitored and the monitoring sensor. In a typical arrangement, the sensor is a piece of alloy made from the same alloy as the corrodible metal article. The sensor and the alloy are connected through a “zero-resistance” ammeter, which measures the current flowing between them. Since two pieces of the same alloy do not make a galvanic couple, the only source of current noise is due to pitting and other types of corrosion. The zero resistance ammeter reports the current, and the characteristics of the current is used to identify the localized pitting corrosion. The noise technique is useful as long as an electrical connection to the alloy is available and affordable. However, there are a number of situations including, for example, steel reinforced concrete structures, where direct electrical contact with the alloy is too difficult, and virtually impractical.

Other monitoring techniques include those reported by J. G. Bellingham and M. L. A. MacVicar in “Detection of Magnetic Fields Generated by ElectroChemical Corrosion”, Electrochemical Society Journal, pp. 1753-54 (August 1986) and J. G. Bellingham and M. L. A. MacVicar in “SQUID Technology Applied to the Study of Electrochemical Corrosion”, IEEE Transactions on Magnetics, Vol. MAG-23, No. 2, pp. 477-79 (March 1987). Each of these articles disclose the use of a SQUID gradiometer to observe corrosion currents in a small electrochemical cell in a laboratory environment for detection of general corrosion. However, the authors did not monitor corrosion rates or suggest that localized corrosion rates could be determined by magnetic field detection.

U.S. Pat. Nos. 5,087,670 and 5,126,654 to Murphy et al. disclose non-invasive detection of electrical currents and electrochemical impedances at spaced localities along a pipeline that is generated on the pipeline by impressing an electrical potential or an electrical current on the pipeline and then measuring the current remaining at various locations on the pipeline.

It would therefore be desirable to provide an improved method for detecting the onset of and/or monitoring the progress of localized corrosion such as pitting corrosion of the corrodible metal article that employs a magnetic field corrosion sensing device which does not need to be in electrical contact with the corrodible metal article in the corrosive environment and does not need to impress a voltage or current into the corrodible metal article such that the magnetic field corrosion sensing device can measure local current distribution, i.e., the magnetic field, of the localized corrosion associated with the corrodible metal article resulting in a more accurate and reliable determination of the progress of localized corrosion.

### SUMMARY OF THE INVENTION

It is an object of the present disclosure to provide a method for detecting the onset of and/or monitoring the progress of localized corrosion, particularly localized pitting corrosion, of a location on the surface of a corrodible metal article in a corrosive environment by placing a magnetic field corrosion sensing device, e.g., a magnetometer, in juxtaposition with the corrosive metal article such that the magnetic field corrosion sensing device can effectively measure the magnetic field associated with the localized corrosion of the location on the surface of the corrodible metal article and determine the localized corrosion rate of the location being monitored.

In accordance with the present invention, a method for detecting the onset of and/or monitoring the progress of localized corrosion of one or more locations on the surface of a corrodible metal article in a corrosive environment is provided comprising the step of placing one or more magnetic field corrosion sensing devices in juxtaposition with the corrosive metal article such that the magnetic field corrosion sensing devices can effectively measure the magnetic fields associated with the localized corrosion of the locations on the surface of the corrodible metal article and determine the degree of localized corrosion occurring at the locations on the surface of the corrodible metal article being monitored.

Further in accordance with the present invention, a method for determining the localized corrosion rate of one or more locations on the surface of the corrodible metal article in a corrosive environment is provided comprising the step of placing one or more magnetic field corrosion sensing devices in juxtaposition with the corrosive metal article such that the magnetic field corrosion sensing devices can effectively measure the magnetic fields associated with the localized corrosion of the locations on the surface of the corrodible metal article and determine the degree of localized corrosion occurring at the locations on the surface of the corrodible metal article being monitored.

A particularly preferred embodiment of the present invention is a method for determining localized pitting corrosion of one or more locations on the surface of a corrodible metal article in a corrosive environment comprising the step of placing one or more magnetic field corrosion sensing devices in juxtaposition with the corrosive metal article such that the magnetic field corrosion sensing devices can effectively measure the magnetic fields associated with the localized pitting corrosion of the locations on the surface of the corrodible metal article and determine the degree of localized pitting corrosion occurring at the locations on the surface of corrodible metal article being monitored.

It has been discovered that utilizing magnetic field corrosion sensing devices at specific locations along the surface of corrodible metal articles pitting and other forms of localized corrosion at specific locations along the surface of corrodible metal articles can be continuously monitored by placing the magnetic field corrosion sensing devices in juxtaposition with the metal article to measure the magnetic fields associated with pitting and other forms of localized corrosion without (1) direct electrical contact between the magnetic field corrosion sensing device and the corrodible metal article, (2) the use of an electrode, and (3) voltage or current perturbation.

### BRIEF DESCRIPTION OF THE DRAWINGS

FIG. 1 is a diagram of the experimental set up for the examples.

FIG. 2A is a graphical representation of the current vs. time of a steel rebar immersed in an aqueous solution of 0.1 M sodium sulfate in water using an 11-ohm resistor.

FIG. 2B is a graphical representation of the current vs. time of a steel rebar immersed in an aqueous solution of 0.1 M sodium sulfate in water using a magnetometer.

FIG. 3A is a graphical representation of the current vs. time of a steel rebar immersed in an aqueous solution of 10% FeCl₃ containing 0.14 M equivalence NaOH using an 11-ohm resistor.

FIG. 3B is a graphical representation of the current vs. time of a steel rebar immersed in an aqueous solution of 10% FeCl₃ containing 0.14 M equivalence NaOH using a magnetometer.

FIG. 4A is a graphical representation of the current vs. time of the same system of FIG. 3A 15 minutes after immersion of the steel rebar in an aqueous solution of 10% FeCl₃ containing 0.14 M equivalence NaOH using an 11-ohm resistor.

FIG. 4B is a graphical representation of the current vs. time of the same system of FIG. 3B 15 minutes after immersion of the steel rebar in an aqueous solution of 10% FeCl₃ containing 0.14 M equivalence NaOH using a magnetometer.

FIG. 5A is a graphical representation of the current vs. time immediately after immersion of the steel rebar in an aqueous solution of 10% FeCl₃ containing 0.14 M equivalence NaOH using an 11-ohm resistor.

FIG. 5B is a graphical representation of the current vs. time immediately after immersion of the steel rebar in an aqueous solution of 10% FeCl₃ containing 0.14 M equivalence NaOH using a magnetometer.

### DESCRIPTION OF THE PREFERRED EMBODIMENTS

The invention provides a method for detecting and monitoring localized corrosion of a corrodible metal article in a corrosive environment employing a magnetic field corrosion sensing device.

A corrosive environment includes any environment containing a corrosive medium which may cause localized corrosion of an object or article exposed to that environment. Examples of corrosive media include, but are not limited to, flowing or non-flowing fluids such as gases, e.g., process exhaust fumes and natural gas, liquids, e.g., hydrocarbons such as, for example, gas crude oil, fuel oil, gasoline, etc., acids, bases, salt solutions, electrolytes, organic and inorganic solvents, oils, water, seawater and the like and combinations thereof.

A corrodible metal article includes any object or article comprising a metal, which is capable of becoming corroded in a corrosive environment containing a corrosive medium as described above. According to the invention, the term “metal” includes any metal alloy, or combinations of metals and nonmetals. Suitable metals include, but are not limited to, iron, steels, e.g., carbon steel, stainless steel, super alloy steels, etc., copper, zinc, aluminum, titanium, and alloys and combinations thereof. The corrodible metal article may be in any shape or form. For example, such articles can be in the form of rebars, storage, tanks, chambers, ducts or tubes, composite materials, etc. The corrodible metal articles may also be embedded in, for example, concrete, soil, composite materials such as epoxy with or without reinforcing materials such as carbon fiber, or immersed in or exposed to fluids such as gases, e.g., and natural gas, liquids, e.g., hydrocarbons such as, for example, gas crude oil, fuel oil, gasoline, etc., acids, bases, salt solutions, electrolytes, organic and inorganic solvents, oils, water, seawater and the like or the corrodible metal article may have the corrosive medium contained therein such as, for example, a metal storage tank containing chemical reagent such as acids, bases or an alkali medium, e.g., potassium hydroxide, sodium hydroxide and mixtures thereof.

In the practice of the present invention, one or more magnetic field corrosion sensing devices can be placed either directly in contact with the surface of the corrodible metal article, e.g., in the case of a storage tank containing a chemical reagant the magnetic field corrosion sensing device can be placed anywhere in the tank, i.e., either placed above the top level of the chemical reagents or immersed in the chemical reagents, or at distances from the locations on the surface of the corrodible metal article to be monitored that are sufficient to effectively measure the magnetic field of localized corrosion associated with the locations on the surface of the corrodible metal article, e.g., in the case of a rebar embedded in concrete. The magnetic field sensing device can be directly contacted by any conventional technique, e.g., adhesives such as an epoxy, Velcro, etc. It is also contemplated that the magnetic field corrosion sensing device can be placed outside the corrosive environment but at a distance sufficient to effectively measure the measure the magnetic field associated with the localized corrosion of the location on the surface of the metal article. Accordingly, to monitor pitting and other localized corrosion in structures the magnetic field corrosion sensing device is advantageously employed herein without direct electrical contact or the use of an electrode and without voltage or current perturbation. As one skilled in the art will readily appreciate, the number of magnetic field corrosion sensing devices necessary to determine the corrosion rate of localized corrosion at various areas on the surface of the metal article will depend on such factors as, for example, the size of the metal article, the areas necessary for the structure to remain intact such as in the case of a bridge where certain areas need monitoring for corrosion else preventive measures cannot be implemented, without which the bridge could ultimately collapse.

By employing the magnetic field sensing device either in direct contact with or at a distance from the location on the surface of the corrodible metal article, the magnetic field corrosion sensing device only senses the currents that flow within the length of the article that is equivalent to the liftoff distance between device and the surface of the article that is related to the localized corrosion. In other word, the magnetic field corrosion sensing device only measures the magnetic field associated with the localized corrosion of the location of the article being monitored and does not sense the ambient magnetic fields which are not due to the localized corrosion activities, but rather arises from surrounding noise, such as, for example, the earth's magnetic field, uniform corrosion and other ambient noise in the measuring environment. Therefore, the device can be used to discriminate between different concurrently occurring localized activities. If desired, one or more surfaces of the magnetic field corrosion sensing device not facing the metal article being monitored, e.g., in the case where the device is monitoring a the localized corrosion of a steel rebar embedded in cement, can have a material applied on at least a portion of the surface(s) to substantially shield the surfaces from ambient noise (i.e., ambient magnetic fields), e.g., in the case where a high level of ambient noise is generated such as ambient noise from vehicles traveling on a bridge or roadway. Preferably all of the surfaces not facing the metal article will have the material applied thereon when necessary. Suitable materials include any material known in the art to substantially shield ambient noise such as, for example, foils of permalloy, alloys of nickel, etc. The material can be applied by conventional techniques, e.g., applying a coating of the material to the surface or by way of an adhesive. Alternatively, the sides of the device not facing the metal article can be removed and then replaced with the material used to substantially shield the device from the ambient noise.

It is particularly advantageous to employ herein as the magnetic field corrosion sensing device a magnetometer as they are currently available and commercially sold for use in the present invention. Suitable magnetometers which may be used herein are those with the following specifications (or better): Sensitivity: about 100 microvolt/nanotesla; Frequency Range (Bandwidth): about 1 micro Hertz to about 300 Hertz (Hz); Noise: less than or equal to about 25 picotesla RMS/\sqrt{Hz}@ 1 Hz. An example of such a magnetometer is the Billingsley TFM 100-2, manufactured by Billingsley Magnetics, 2600 Brighton Dam Road, Brookeville, Md. 20833, USA. Another magnetomer which may also be used herein is the Magnetometer Model #533 available from Applied Physics Systems, located at 1245 Space Park Way, Mountain View, Calif. 94043, USA. These magnetometers are small, and therefore, easily placed along the surface of most corrodible metal articles.

In use, the magnetic field corrosion sensing device may be electrically connected to a signal data collector to collect data over an extended period of time only when the magnetic field corrosion sensing device senses localized corrosion activities. The signal data collector comprises a computer microprocessor for system operation and control, and for using corrosion algorithms for calculating type, location, size, and rate of corrosion. Accordingly, the magnetic field corrosion sensing device can remain in juxtaposition with the corrodible metal article along with the signal data collector for extended times so that one could easily identify the periods of corrosion activity and the cumulative damage to the article or structure. Alternatively, it is also contemplated to connect the output of the magnetic field corrosion sensing device to wireless transmitters, and collect the data using, for example, a receiver placed at a further but convenient distance from the device. Thus, using multiple sensing devices connected either to a local microprocessor/data collector and/or transmitters, one can monitor continuously and remotely corrosion activities from multiple locations. This determination of corrosion conditions can be analyzed to survey the structural integrity of corrodible metal articles which are subjected to corrosive environments. The parameters of importance depend on the environment conditions, and are easily determinable by those skilled in the art.

The following non-limiting example is illustrative of the present invention by using a magnetometer to monitor pitting corrosion current in steel.

### EXAMPLES

Experimental Setup

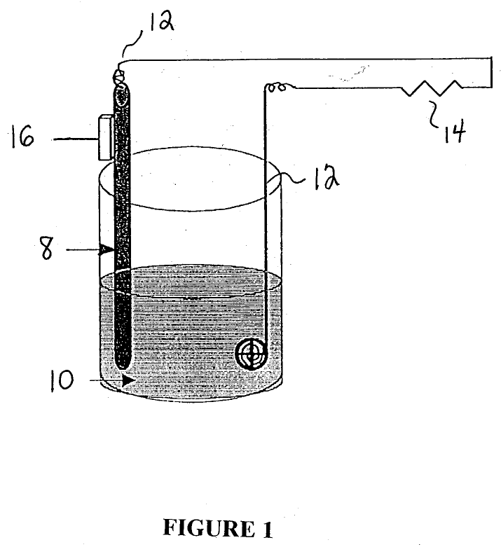

FIG. 1 illustrates the experimental setup. This example consisted of testing a 0.5-in.-diameter, 2-ft.-long carbon steel rebar 8, commonly used as reinforcing metal in concrete. First, the pre-existing corrosion products on rebar 8 were removed by grinding and polishing the rebar to allow the bare metal surface to contact electrolyte solution 10 used as the corrosive medium. The area of rebar 8 exposed to the corrosive medium was about 5.5 cm². The corrosion process was further accelerated by galvanic action, forced by connecting the top end of rebar 8 (also polished for good electrical contact) to a platinum coil 12 that was also immersed into the same electrolyte solution 10. An 11-ohm resistor 14 was placed in series between rebar and platinum coil 12 to prevent excessive corrosion induced by the galvanic action. A three-axis magnetometer 16 was placed close to rebar 8 and measured the magnetic field on and around rebar 8. The sides of the magnetometer 16 not facing the rebar 8 were covered with a material such as permalloy, to shield the magnetometer 16 from ambient magnetic fields. Two of the three sensing coils in magnetometer 16, oriented orthogonal to the long-axis of the rebar, were capable of sensing the current on rebar 8. In the arrangement shown in FIG. 1, the coil that is oriented parallel to the plane of the paper (x-axis) is more sensitive than the one that is oriented perpendicular to the plane of the paper.

The electrolyte solution was an aqueous solution of 0.1 M sodium sulfate (Na₂SO₄) in water for one set of comparative examples and a 10% (by weight) solution of iron chloride (FeCl₃) in water with pH adjusted to about 13 by addition of NaOH for a second set of examples to illustrate localized corrosion. The 0.1 M Na₂SO₄ solution was used to cause the steel rebar to corrode uniformly; as it does not, in general, cause steel to pit. The 10% FeCl₃ solution was used to cause the steel rebar to pit and adjusting the pH of this solution allowed for controlling the rate of pitting.

The electrochemical corrosion process, whether general or pitting, generates an electric current. In the example shown in FIG. 1, coupling the steel rebar 8 to a platinum wire 12 generated a galvanic cell, and the current flowed through the steel rebar and the lead wire. The magnetometer 16 (Billingsley Model TFM 100-2 available from Billingsley Magnetics, Brookeville, Md.) was placed near the rebar to sense the magnetic field generated by the current. The sensitivity of magnetometer 16 was 100 microvolt per nanotesla (μV/nT). Furthermore, the current flow across the 11-Ω resistor 14 also generated a potential drop, which provided a direct measure of the amplitude of the current flow. For testing purposes, any resistor between 5- to 100-Ω should be applicable, as long as they are not too small to accelerate the corrosion process. The resistor, unlike the magnetometer, provided a direct measure of the current. In a real-world application, it may not be possible to use a resistor (or a zero-resistance ammeter) to measure the current flow, unless the rebar is accessible for direct electrical connections. However, one could use a magnetometer, even where direct electrical connections to the rebar is impractical. In the present experiment, we used the 11-Ω resistor as a convenient way to verify and validate the current sensed by the magnetometer. Each experiment was conducted at room temperature (21±1° C.).

Using a two-channel FFT Analyzer (Advantest R9211 C available from Tektronix, Inc., Gaithersburg, Md.), a simultaneous current vs. time (I-t) record from the output of the magnetometer and across the 11-Ω resistor was made. The analyzer was AC-coupled, and was set to a bandwidth of 2.558 Hz or 0.391 seconds/data point. The direct current generated by the galvanic action, and all the high frequency (>3 Hz) noise including the 60 Hz and its harmonics presumably present in most electronic equipment was rejected from the recordings.

Characteristics of Current Generated by Pitting Corrosion

It was easy to distinguish the current generated by pitting corrosion from the current generated by uniform corrosion. Typically, the current due to pitting is “noisy,” and fluctuates sharply; the current noise has frequency components in about 0.1 to about 1 Hz range. The current due to uniform corrosion is relatively less noisy, with typical frequency components in the range less than about 0.1 Hz. The frequency components of the corrosion current noise could be characterized by Fourier transform (FFT) techniques to get detailed information on localized corrosion processes. For the purpose of these experiments, it was adequate to recognize and distinguish the widely fluctuating current noise caused by pitting corrosion from the gently fluctuating current noise due to uniform corrosion.

Results and Discussions

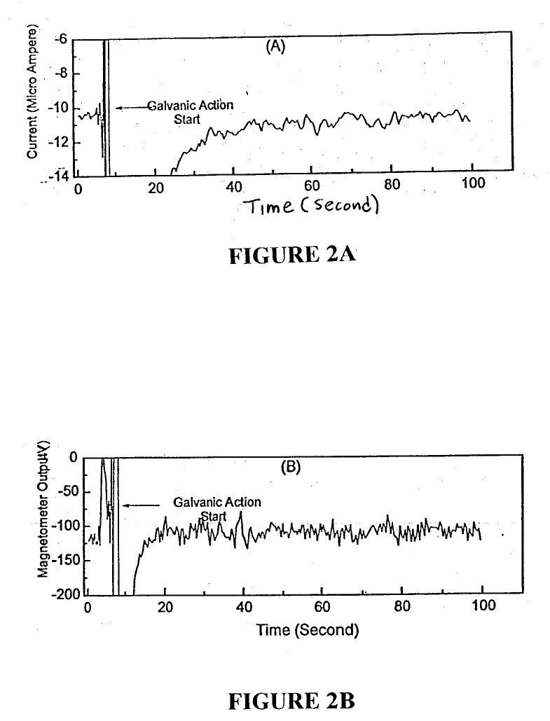

First, one set of I-t data for the steel rebar immersed in the aqueous solution of 0.1 M Na₂SO₄ was collected by measuring the current across the 11-Ω resistor and with the x-axis of the magnetometer, with the results being presented in FIGS. 2A and 2B, respectively. The arrow in the figure indicating “Galvanic Action Start” refers to the point in time when the steel rebar and the platinum coil were connected to each other through the 11-Ω resistor. Immediately after the start of the galvanic action, the current went through a transient change (due to the charging of the double layer capacitance), and came to a near steady state value after about 30 seconds. The amplitudes of the fluctuations in the current (FIG. 2A) were less than 2 μA, too small to be attributed to pitting corrosion. The amplitudes of the output of the magnetometer (FIG. 2B) were on the order of few tens of micro volt (μV), and does not correlate with the current registered across the resistor. The fluctuations in the data in FIG. 2A and FIG. 2B were most probably instrumentation noise, and unrelated to the corrosion of the metal.

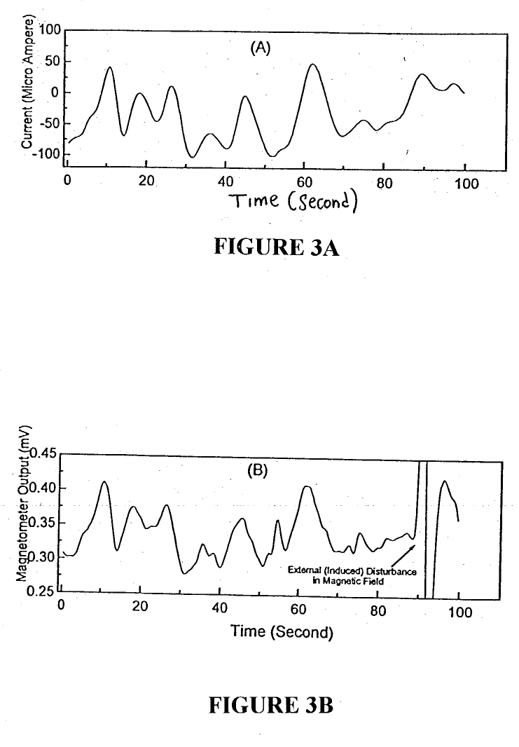

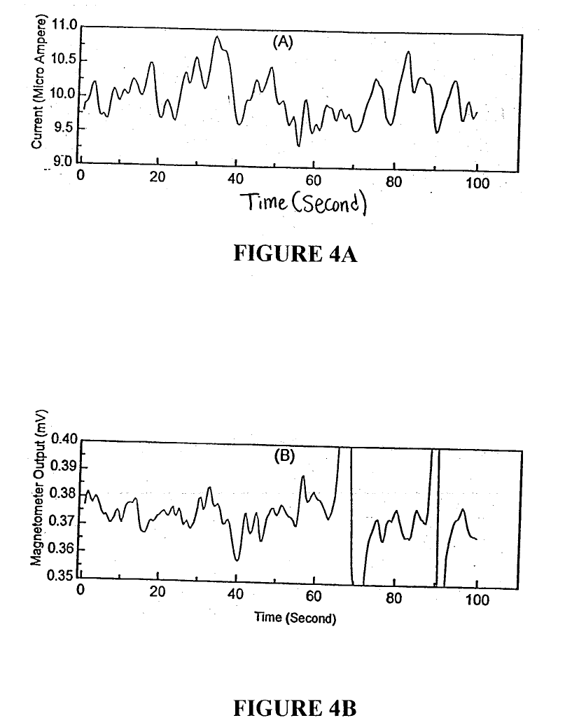

Next, the sodium sulfate aqueous solution was replaced with an aqueous solution of 10% FeCl₃ containing 0.14 M equivalence of sodium hydroxide (pH of about 13) and recorded the current immediately (FIG. 3). As shown in FIG. 3A, a fluctuating current of about 100-150 μA, which was much larger than the current observed in the sodium sulfate (FIG. 2A). The magnetometer data shown in FIG. 3B correlated well with the current data in FIG. 3A, suggesting that when the corrosion current noise was well above the instrumentation noise (FIG. 2B) the magnetometer sensed the corrosion current signal on the steel rebar rather easily. When the corroding system was left undisturbed for about 15 minutes, the current due to corrosion was reduced considerably, from about 150 to about 1 μA (see FIG. 4A). The reduction in the current fluctuations might have been caused by the formation of a passivation layer on the surface of the steel rebar since at a pH of about 13, steel was known to passivate thus preventing chloride-induced corrosion, at least temporarily. When the currents were low (<about 1 μA), the magnetometer output (see FIG. 4B) correlated with the current data in FIG. 4A only partially. Thus, the data in FIGS. 4A and 4B represented the lower limit of the current noise that the magnetometer (Billingsley Model TFM 100-2) was able to register. However, the less than 1 μA (or 0.2 μA/cm² current density) was too small to cause serious corrosion, hence the lower limit of the sensitivity of the magnetometer may not be detrimental to its ability to detect corrosion that caused real damage.

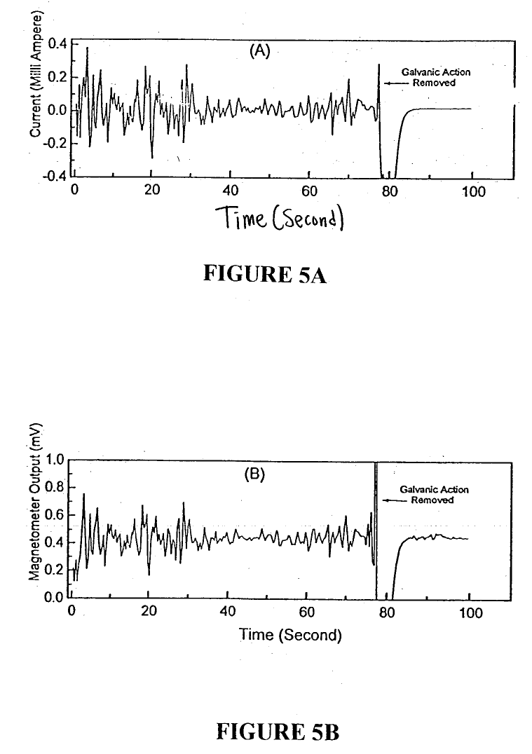

Note that before we caused the steel rebar to generate corrosion noise in the 10% FeCl₃ solution (data in FIGS. 3 and 4) we had immersed the rebar in a solution of 0.1 M sodium sulfate. The exposure of the steel to the sulfate medium was likely to have lead to the formation of iron sulfate, turned into a weak passivation layer at pH of about 13, and a relatively small corrosion noise even in presence of FeCl₃. Therefore, an additional test was carried out by placing a freshly polished steel rebar into the FeCl₃ solution of pH 13, and recorded the current almost immediately after immersion. The polishing removed any corrosion product that might have formed during the earlier exposure to the sodium sulfate solution thus leaving the surface vulnerable to corrosion attack in the FeCl₃ medium. The resulting corrosion currents (FIGS. 5A and 5B) were significantly higher both in amplitude and in frequency than the one seen in FIG. 3. The correlation between the magnetometer output and the current through the resistor was also quite strong suggesting that the magnetometer was able to sense the localized corrosion-generated by the current noise without any difficulty.

Advantages of Using Magnetometers for Localized Corrosion Monitoring

As mentioned earlier, the forms of localized corrosion that are detrimental to corrodible metal articles are pitting, crevice, SCC, and hydrogen embrittlement. They do not occur continuously, and they are hard to measure or monitor. Techniques such as, for example, ac impedance, linear or logarithmic polarization, etc., are useful to measure corrosion rate, only if corrosion is occurring at the time of the measurement. They are contact techniques, which are too difficult, if not impossible, to use on articles that are immersed or embedded in a poorly conducting gas, liquid, or solid medium that is capable of corroding the article. They need a voltage or current stimulus to make the corroding metal article respond, even when the structure was immersed in a conducting medium (electrolyte). They are not useful to measure the corrosion rate in air and other non-liquid or liquid mediums. Even when they work, they provide only the corrosion rate due to uniform corrosion. They are not useful in measuring localized corrosion. Even noise techniques that use ammeters, resistors or electrodes to sense localized corrosion, work only if direct contact with the metal can be established.

To monitor pitting and other localized corrosion in structures without contact, without the use of an electrode, and without voltage or current perturbation, independent of the condition of whether the structure is or not in contact with a liquid, one needs a corrosion current sensing element. Magnetometers including the one used herein (Billingsley Model TFM 100-2) are small, therefore, easily attached to most structures. They are battery operated, therefore easy to use in the field. Furthermore, a magnetometer is also a powerful tool to measure corrosion rate with high spatial resolution. It only senses the currents that flow within the length of the structure that is equivalent to the liftoff distance between magnetometer and the surface of the structure. Therefore, it can be used to discriminate between different concurrently occurring localized activities. Because of the small size, low power demand, non-contact way to monitor localized corrosion, magnetometers lend themselves to two important modes of operation. First, they can be easily connected to a small microprocessor that collects the data only when the magnetometer senses corrosion activities. In other words, by leaving a magnetometer along with a data logger placed at a distance from a corrodible metal article which is sufficient to sense the magnetic field of the localized corrosion of the article for extended times, one could easily identify the periods of corrosion activity and the cumulative damage to the structure. Second, one could connect the output of the magnetometers to wireless transmitters, and collect the data using a receiver placed at a farther but convenient distance from the sensor. Thus, using multiple magnetometers connected either to a local microprocessor/data logger and/or transmitters, one can monitor continuously and remotely corrosion activities from multiple locations.

Conclusion

Steel rebar undergoes localized corrosion when exposed to an aqueous solution of 10% FeCl₃. The corrosion process generated current noise with frequency content in the range of about 0.1 to 1 Hz, and amplitude less than about 1 μA/cm². The amplitude and frequency of the corrosion current vary with the medium of corrosion, and time of exposure and the previous history of the alloy. A magnetometer that has a sensitivity of about 100 μV/nT (microvolt per nanotesla), and placed at a distance of <1 cm from the rebar, was able to sense the corrosion current noise that is about 1 μA or more. The signal/noise ratio improves as the amplitude of the corrosion current noise increases above 1 μA/cm². Corrosion currents less than about 1 μA/cm² may not cause serious damage to a structure, and those above 10:A/cm² are damaging and detrimental to the alloy and the structure. Thus, in the range where corrosion could cause damage to a structure, the magnetometer was able to sense and report the current.

A magnetometer and a 11-Ω resistor were used to monitor the current. The resistor was only for the purpose of verifying and correlating the magnetometer signal with the actual corrosion current. (A zero-resistance ammeter could easily replace a resistor to measure current.) However, in real structures, it is virtually impractical to use a resistor or an ammeter to measure corrosion currents, because they need direct electrical contact to the metal. The magnetometer, on the other hand, is a non-contact sensor, and is ideally suited to sense corrosion current noise. The use of a magnetometer for sensing corrosion current noise is particularly attractive if the metal is buried (such as steel rebar in concrete) or otherwise inaccessible.

The carbon steel used in the examples is only a representative case of an alloy capable of undergoing localized corrosion. Other metals and alloys such as stainless steel, aluminum, and titanium, all used as structural elements, are also capable of undergoing localized corrosion. Thus, the magnetometer-based technique can be used to monitor localized corrosion in virtually any metallic structure.

The magnetometer used in this work was small (3.51×3.51×15.37 cm; 182 grams) and operated using a 12 V, 35 mA battery. There are other magnetometers available in the market with comparable sensitivity. They are also much smaller magnetometers such as Model #HMC2003 by Honeywell with the magnetometer sensor and electronics integrated on a 2×2×0.25-cm chip, and consume much less power than the Billingsley Model TFM 100-2 example discussed earlier. One could install them in large numbers in small spaces such as inside the walls of airplane fuselage. By coupling the magnetometers with microprocessor-based data loggers, or miniature data transmitters developed elsewhere, one could record the corrosion activity over long and extended periods. The stream of data could be used to estimate accumulated damage caused by corrosion, raise an alarm and then plan, repair and maintenance of the corrodible article could be achieved.

It will be understood that various modifications may be made to the embodiments disclosed herein. Therefore the above description should not be construed as limiting, but merely as exemplifications of preferred embodiments. For example, the functions described above and implemented as the best mode for operating the present invention are for illustration purposes only. Other arrangements and methods may be implemented by those skilled in the art without departing from the scope and spirit of this invention. Moreover, those skilled in the art will envision other modifications within the scope and spirit of the claims appended hereto.

What is claimed is:

1. A method for detecting the onset of and/or monitoring the progress of localized corrosion of one or more locations on the surface of a corrodible metal article in a corrosive environment comprising the step of placing one or more magnetic field corrosion sensing devices in juxtaposition with the surface of the corrosive metal article such that the magnetic field corrosion sensing devices can effectively measure the magnetic fields associated with the localized corrosion of the locations on the surface of the corrodible metal article and determine the degree of localized corrosion occurring at the locations on the surface of the corrodible metal article being monitored.

2. The method of claim 1 wherein the corrodible metal article is a metal or combination of metals and nonmetals.

3. The method of claim 1 wherein the metal is selected from the group consisting of iron, carbon steel, stainless steel, super alloy steel, copper, zinc, aluminum, titanium, and alloys and combinations thereof.

4. The method of claim 1 wherein the corrodible metal article is a rebar, storage tank, chamber, duct, tube or composite material.

5. The method of claim 1 which further comprises collecting a series of magnetic field measurements with a signal data collector electrically connected to the magnetic field corrosion sensing device.

6. The method of claim 5 wherein the signal data collector comprises a computer microprocessor.

7. The method of claim 1 which further comprises collecting a series of magnetic field measurements from the magnetic field corrosion sensing device with a wireless transmitter.

8. The method of claim 1 wherein the magnetic field corrosion sensing device is a magnetometer.

9. The method of claim 1 wherein the magnetic field corrosion sensing device is placed directly in contact the corrodible metal article.

10. The method of claim 1 wherein the magnetic field corrosion sensing device is placed at a distance from the corrodible metal.

11. The method of claim 1 wherein the magnetic field corrosion sensing device is placed outside the corrosive environment.

12. The method of claim 1 wherein the magnetic field corrosion sensing device is placed in the corrosive environment.

13. The method of claim 1 wherein the localized corrosion to be monitored is selected from the group consisting of pitting corrosion, crevice corrosion, hydrogen embrittlement, stress corrosion cracking and combinations thereof.

14. The method of claim 1 wherein one or more of the surfaces of the magnetic field corrosion sensing device not facing the corrodible metal article have a material applied on at least a portion thereof to substantially shield the device from ambient noise.

15. A method for determining the localized corrosion rate of one or more locations on the surface of a corrodible metal article in a corrosive environment comprising the step of placing one or more magnetic field corrosion sensing devices in juxtaposition with the surface of the corrosive metal article such that the magnetic field corrosion sensing devices can effectively measure the magnetic fields associated with the localized corrosion of the locations on the surface of the corrodible metal article and determine the degree of localized corrosion occurring at the locations on the surface of the corrodible metal article being monitored.

16. The method of claim 15 wherein the corrodible metal article is selected from the group consisting of iron, carbon steel, stainless steel, super alloy steel, copper, zinc, aluminum, titanium, and alloys and combinations thereof.

17. The method of claim 15 wherein the corrodible metal article is a rebar, storage tank, chamber, duct, tube or composite material.

18. The method of claim 15 which further comprises collecting a series of magnetic field measurements with a signal data collector electrically connected to the magnetic field corrosion sensing device.

19. The method of claim 18 wherein the signal data collector comprises a computer microprocessor.

20. The method of claim 15 which further comprises collecting a series of magnetic field measurements from the magnetic field corrosion sensing device with a wireless transmitter.

21. The method of claim 15 wherein the magnetic field corrosion sensing device is a magnetometer.

22. The method of claim 15 wherein the magnetic field corrosion sensing device is placed directly in contact the corrodible metal article.

23. The method of claim 15 wherein the magnetic field corrosion sensing device is placed at a distance from the corrodible metal article.

24. The method of claim 15 wherein the magnetic field corrosion sensing device is placed outside the corrosive environment.

25. The method of claim 15 wherein the magnetic field corrosion sensing device is placed in the corrosive environment.

26. The method of claim 15 wherein the localized corrosion to be monitored is selected from the group consisting of pitting corrosion, crevice corrosion, hydrogen embrittlement, stress corrosion cracking and combinations thereof.

27. The method of claim 15 wherein one or more of the surfaces of the magnetic field corrosion sensing device not facing the corrodible metal article have a material applied on at least a portion thereof to substantially shield the device from ambient noise.
